(19) United States
(12) Patent Application Publication
(10) Pub. No.: US 2012/0255609 A1
(43) Pub. Date: Oct. 11, 2012

(54) SOLAR CELL MODULE

(75) Inventors: Susumu SOBUE, Obu-city (JP); Shoichi KAWAI, Kuwana-city (JP); Tomomi TAKAGI, Nagoya-city (JP); DaeGwi KIM, Osaka-city (JP)

(73) Assignees: OSAKA CITY UNIVERSITY, Osaka-city (JP); DENSO CORPORATION, Kariya-city (JP)

(21) Appl. No.: 13/439,212

(22) Filed: Apr. 4, 2012

(30) Foreign Application Priority Data
Apr. 8, 2011 (JP) 2011-86604

(51) Int. Cl. H01L 31/0232

(52) U.S. Cl. 136/257

(57) ABSTRACT

A solar cell module includes: a solar cell; a protection plate having transparency and disposed on a light receiving side of the solar cell; and a wavelength conversion layer converting a wavelength of light and disposed between the solar cell and the protection plate. The wavelength conversion layer includes a particle, which is dispersed in the wavelength conversion layer. The particle absorbs light having a predetermined wavelength. The particle includes an element as a light emission center for emitting light having a wavelength larger than absorbed light.

### CROSS REFERENCE TO RELATED APPLICATION

This application is based on Japanese Patent Application No. 2011-86604 filed on Apr. 8, 2011, the disclosure of which is incorporated herein by reference.

### TECHNICAL FIELD

The present disclosure relates to a solar cell module.

### BACKGROUND

Conventionally, a solar cell module is well known such that the module has a structure that a solar cell is sandwiched between a back sheet and protection glass, and the solar cell is sealed with a sealing member.

In the module, it is required to utilize ultraviolet light effectively for electric generation. Thus, recently, in order to utilize effectively solar energy in an ultraviolet radiation spectrum region, a sealing layer made of ethylene-vinyl acetate copolymer is arranged between the protection glass and the back sheet, and the solar cell is arranged in the sealing layer. This technique is disclosed in JP-A-2008-235610. In this technique, the light transmission rate at a wavelength of 360 nanometers is equal to or larger than 40 percents. Thus, the power generation efficiency is improved. Further, the light transmission rate at a wavelength of 360 nanometers is equal to or smaller than 70 percents, so that the damage of the sealing member caused by the ultraviolet light is restricted.

When the solar cell is made of organic material, the solar cell may be damaged by the ultraviolet light. In order to protect the cell from the ultraviolet light, the ultraviolet light is blocked, so that light resistance is improved. Further, in this case, when the solar cell module includes a light conversion film for emitting light in a band, in which a energy efficiency is high, the power generation efficiency is improved. Specifically, the material of fluorescent material in the light conversion film has a relationship of “Eg<3.35 eV,” which corresponds to the relationship that the light absorption wavelength is smaller than 370 nanometers. For example, the fluorescent material in the light conversion film is made of ZnSe or CdS. The light emission wavelength is defined as the wavelength of the light emission caused at a crystal defect. This is disclosed in JP-A-H11-345993.

Further, recently, in order to effectively utilize the light having a comparatively short wavelength, a wavelength conversion layer is arranged on an input side of the solar cell. Further, in order to emit light according to resonant energy, the wavelength conversion layer includes an input quantum dot and an output quantum dot. This is described in JP-A-2009-223309.

However, in the technique described in JP-A-2008-235610, when the solar cell is a conventional silicon crystal solar cell (Si solar cell), the power generation efficiency at the wavelength of 360 nanometers is very low. Thus, even if the light transmission rate of the ultraviolet light is high, the power generation efficiency is not much improved.

Further, in the technique described in JP-A-H11-345993, since the light conversion film is an inorganic thin film, the band gap is fixed. Thus, it is difficult to adjust the absorption wavelength correctly. Further, since the light emission center is a defect generated in a forming step of the inorganic thin film. Thus, the energy conversion efficiency is not high, and therefore, the brightness of the light emission is very low. Furthermore, it is difficult to emit light when the fluorescent material in the light conversion film is made of ZnSe or CdS since the intrinsic defect emits light by an inorganic light emission process so that the energy as heat is lost. Thus, although the damage of the organic material caused by the ultraviolet light is protected, the contribution to the improvement of the power generation efficiency of the solar cell is nogt substantially obtained.

Further, in the technique described in JP-A-2009-223309, the wavelength is converted by the quantum dot. In this case, it is necessary to dope the input quantum dot and the output quantum dot. When the solar cell module includes two types of the quantum dots, it is necessary to transmit the energy according to the resonant phenomena. Unless the quantum dots are dispersed uniformly at predetermined intervals such as a few nanometers, the transmission of the energy does not occur. Accordingly, the cost of the material increases, and the manufacturing process is complicated. It is difficult to put to practical use.

### SUMMARY

It is an object of the present disclosure to provide a solar cell module having high power generation efficiency. Further, the solar cell module is easily and simply manufactured.

According to an example aspect of the present disclosure, a solar cell module includes: a solar cell; a protection plate having transparency and disposed on a light receiving side of the solar cell; and a wavelength conversion layer converting a wavelength of light and disposed between the solar cell and the protection plate. The wavelength conversion layer includes a particle, which is dispersed in the wavelength conversion layer. The particle absorbs light having a predetermined wavelength. The particle includes an element as a light emission center for emitting light having a wavelength larger than absorbed light.

In the above module, although the light having the comparatively short wavelength is not utilized for the solar cell, the converted light having the comparatively long wavelength can be utilized for the solar cell. Thus, the power generation efficiency of the module is improved. Further, since the module has a simple structure compared with a case where the module includes an input quantum dot and an output quantum dot, the module is easily manufactured.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing a cross sectional view of a solar cell module taken along a thickness direction, according to a first embodiment;

FIG. 2 is a diagram showing a plan view of the solar cell module;

FIG. 3 is a graph showing spectral sensitivity characteristic of a solar cell;

FIGS. 4A to 4C are diagrams showing a forming method of a wavelength conversion layer according to the first embodiment, FIG. 4D is a diagram showing a forming method of a wavelength conversion layer according to a second embodiment, and FIGS. 4E to 4G are diagrams showing forming methods of a wavelength conversion layer according to other embodiments;

FIG. 5 is a diagram showing detailed steps of the forming method of the wavelength conversion layer according to the first embodiment;

FIG. 6 is a diagram showing a manufacturing method of the solar cell module according to the first embodiment;

FIG. 7 is a diagram showing a cross sectional view of a solar cell module taken along a thickness direction, according to a second embodiment;

FIG. 8 is a diagram showing a cross sectional view of a solar cell module taken along a thickness direction, according to a third embodiment;

FIG. 9 is a diagram showing a cross sectional view of a solar cell module taken along a thickness direction, according to a fourth embodiment;

FIG. 10A is a diagram showing a manufacturing method of a solar cell module as a test piece for a performance test, FIG. 10B is a diagram showing a cross sectional view of the solar cell module in FIG. 10A, and FIG. 10C is a diagram showing a test method of the performance test;

FIGS. 11A and 11B are diagrams showing cross sectional views of solar cell modules taken along a thickness direction, which are used for the performance test as comparison modules; and

FIG. 12 is a graph showing results of the performance test.

### DETAILED DESCRIPTION

Embodiments of a solar cell module will be explained.

### First Embodiment

A structure of a solar cell module 1 according to a first embodiment will be explained.

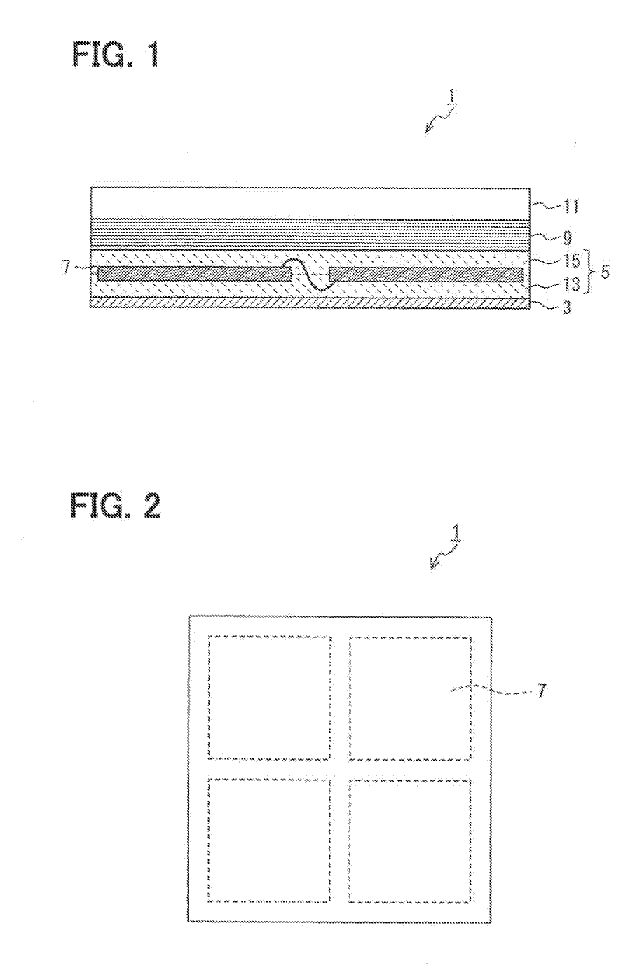

As shown in FIGS. 1 and 2, the module 1 is a plate shaped member having a square plan view. The module 1 includes a solar cell 7 disposed on a surface of a back sheet 3 on a light receiving side (i.e., an upper side of FIG. 1). The solar cell 7 is sealed in a sealing layer 5, which is transparent. Further, the module 1 includes a wavelength conversion layer 9 disposed on a surface of a light receiving side of the solar cell 7. The wavelength conversion layer 9 converts a wavelength of light. Furthermore, the module 1 includes a protection glass 11 on a surface of the light receiving side of the wavelength conversion layer 9. The protection glass 11 is transparent.

Each element of the module 1 will be explained.

The back sheet 3 is made of, for example, plastic material such as polyethylene terephthalate. The back sheet 3 is a plate shaped member.

The sealing layer 5 includes a lower sealing layer 13 disposed on a lower side of the solar cell 7 and an upper sealing layer 15 disposed on an upper side of the solar cell 7. The sealing layer 5 is made of, for example, ethylene-vinyl acetate polymer or silicone resin.

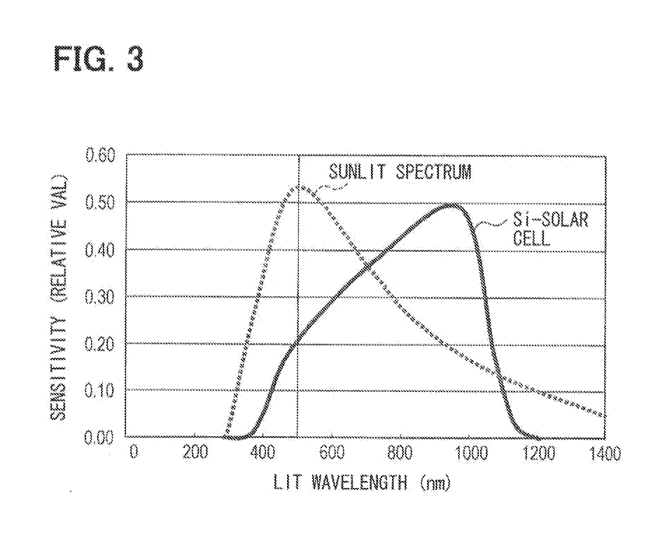

The solar cell 7 has a square plan view. The solar cell 7 is a silicon single crystal solar cell (i.e., silicon solar cell) having a band gap of 1.1 eV. The solar cell 7 has a spectral characteristic shown in FIG. 3. Here, FIG. 3 shows a spectral characteristic of a sunlight spectrum and a spectral characteristic of a silicon solar cell. Multiple solar cells 7 in the module 1 are coupled with each other in series.

The protection glass 11 is a transparent member made of high transparent glass such as “a Japanese white plate glass” for a solar cell. The wavelength conversion layer 9 is a sheet made of transparent resin having a hydrophilic property, in which nano particles as the quantum dots are uniformly dispersed. Specifically, the transparent resin having the hydrophilic property is, for example, pullulan as glucose polysaccharide. The wavelength conversion layer 9 has translucency so that the layer 9 transmits light having a wavelength equal to or larger than 500 nanometers more than 90 percents.

The nano particle has a diameter of certain nanometers such as one nano meter to twenty nano meters. The nano particle includes an element as a dopant, which is disposed in the nano particle and provides a light emission center. When the nano particle absorbs the light having the wavelength smaller than 500 nanometers, the nano particle emits light having the wavelength equal to or larger than the absorbed light. For example, the nano particle emits light having the wavelength equal to or larger than 500 nano meters.

Specifically, when the band gap (or a diameter) of the nano particle is determined, the nano particle absorbs the light having a predetermined wavelength, and the nano particle emits light having another predetermined wavelength. Thus, the nano particle includes the dopant as the light emission center so that the nano particle functions above.

In the present embodiment, the nano particle is made of ZnSe (zinc selenide) and has a diameter of 3 nanometers. The dopant as the light emission center is made of Mn and disposed in the nano particle. Thus, the nano particle absorbs the light including the ultraviolet light having the wavelength equal to or smaller than 400 nanometers, and the nano particle emits light having the wavelength around 585 nano meters. Here, the band gap of a bulk crystal of the material for providing the nano particle is equal to or larger than 2.48 eV.

The nano particle may be made of various inorganic material such as zinc selenide, cadmium selenide, cadmium sulfide, zinc cadmium selenide, zinc sulfide, calcium sulfide, mixed crystal of zinc selenide sulfide, mixed crystal of cadmium selenide sulfide, and mixed crystal of zinc selenide cadmium sulfide.

The element as the light emission center may be Eu having the light emission wavelength of 690 nanometers, Yb having the light emission wavelength of 980 nanometers, Er having the light emission wavelength of 1500 nanometers, Cu having the light emission wavelength of 450 nanometers, Tb having the light emission wavelength of 550 nanometers and the like.

When the diameter of the nano particle is determined, the wavelength of the light absorbed in the nano particle is set. This effect is described in L. E. Brus, 3. Chem. Phys. Vol. 80, p. 4403 (1984). Thus, this effect is well known. The relationship between the diameter of the nano particle and the wavelength of the light absorbed in the nano particle will be explained as follows.

The optical transition energy defined by E(R) and the radius of the nano particle defined by R have the following relationship F1.

$$E ( R ) = Eg + \frac{{h}^{2}}{2 μ} \cdot {( \frac{π}{R} )}^{2} - 1.8 \frac{{e}^{2}}{ɛ R} \qquad F1$$

Here, Eg represents the band gap energy of the bulk crystal, R represents the radius of the particle, μ represents the reduced mass of the electron and hole, h represents the Planck's constant, ∈ represents the dielectric constant, and e represents the quantum of electricity.

Thus, based on the above relationship F1, the optical transition energy E(R) of the nano particle and the radius R of the particle are determined. The relationship between the energy and the wavelength is “E=1240/λ.” Here, the energy is defined by E having the unit of eV, and the wavelength is defined by λ having the unit of nanometer.

Next, the manufacturing method of the module 1 according to the present embodiment will be explained as follows.

First, a manufacturing process of the film for forming the wavelength conversion layer 9 will be explained.

<Synthesis of Nano Particle>

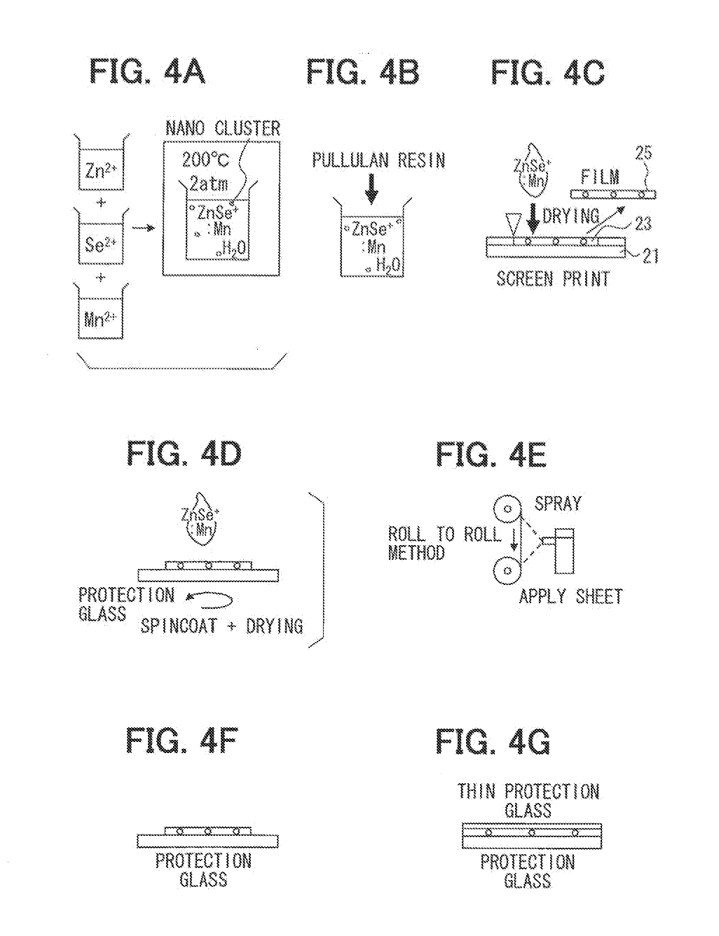

FIG. 4A shows a step for synthesizing the nano particle. As shown in FIG. 4A, the Zn ion source, the Se ion source and the Mn ion source are mixed in water. Then, the mixed liquid is processed by the hydrothermal synthesis method so that the ZnSe nano particle, in which Mn is doped, is prepared. Specifically, the ZnSe nano particle liquid is formed.

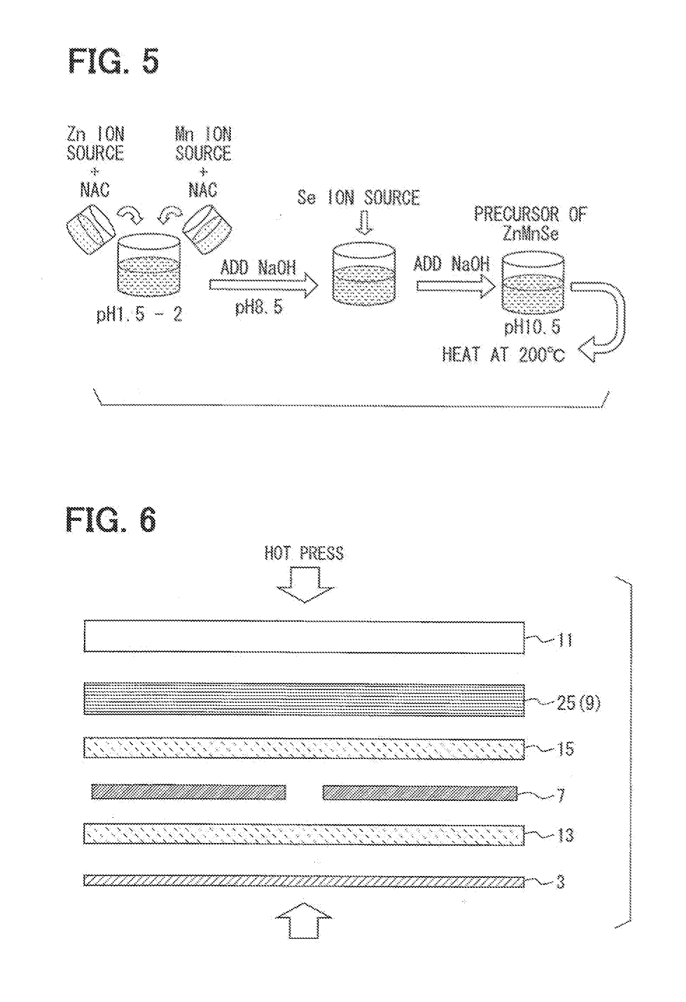

Specifically, as shown in FIG. 5, first, the Zn ion source and the organic ligand such as N-acethyl L cysteine (i.e., NAC) are mixed with a mole ratio of 1:4.8 so that the liquid No. 1 is prepared.

Then, the Mn ion source and the NAC are mixed with a mole ratio of 1:1 so that the liquid No. 2 is prepared.

Then, the liquid No. 1 and the liquid No. 2 are mixed with a ration of 99:1 under a condition of pH in a range between 1.5 and 2.0. Thus, the liquid No. 3 with the Mn concentration of 1% is prepared.

Then, NaOH is added in the liquid No. 3 so that pH is adjusted to be 8.5. Thus, the liquid No. 4 is prepared.

Then, the Se ion source is added in the liquid No. 4 so that the ZnMnSe precursor liquid defined as the liquid No. 5 is prepared. In this case, NaOH is added in the liquid No. 4. The pH of the liquid No. 5 may be adjusted to 10.5. Here, the mole ratio in the liquid No. 5 is the same as the step for synthesizing the ZnSe nano particle in FIG. 4A so that the mole ratio of Zn and Se in the liquid No. 5 is 1:0.6.

Then, 10 milli-litter of the liquid No. 5 is poured into a autoclave reaction container so that the liquid No. 5 is maintained at 200° C. under a pressure of 2 atmospheres. Thus, the liquid No. 5 is heated at 200° C. for a few minutes to 30 minutes so that the ZnSe:Mn nano particle having the diameter in a range between a few nanometers and 8 nano meters is synthesized.

Here, the diameter of the nano particle is controlled by the heating time. For example, the diameter of the nano particle is controlled in a range between 1 nano meter and 20 nano meters.

<Binder Mixture>

Next, as shown in FIG. 4B, the hydrophilic transparent resin as a binder such as pullulan (i.e., glucose polysaccharide) is added in the nano particle liquid such that the ratio between the nano particle and the hydrophilic transparent resin is 1:1. Then, the nano particle liquid with the hydrophilic transparent resin is mixed, so that mixed resin material in paste form is formed. Here, since the nano particle has a hydrophilic property, the hydrophilic transparent resin is used as the binder. Alternatively, when the nano particle has a hydrophobic property, the hydrophobic resin such as silicone resin may be used as the binder.

<Printing Step for Forming a Film>

Next, as shown in FIG. 4C, with using the mixed resin material, a screen printing process is performed on a base 21 so that a printing layer 23 is formed. The printing layer 23 is dried, so that a film 25 including the nano particle is formed. The film 25 provides the wavelength conversion layer 9.

Next, a manufacturing method of the solar cell module 1 with using the film 25 will be explained as follows.

As shown in FIG. 6, the back sheet 3, the lower sealing layer 13, the solar cell 7, the upper sealing layer 15, the film 25 for providing the wavelength conversion layer 9, and the protection glass 11 are stacked in this order. Then, the stacked layers are hot-pressed so that the thermally hardening seal process is performed. Thus, the solar cell module 1 is completed.

Next, the advantages of the module 1 according to the present embodiment will be explained.

In the solar cell module 1, the light as solar light entered from the upper side of the module in FIG. 1 penetrates into the wavelength conversion layer 9 via the protection glass 11. A part of the light entered into the wavelength conversion layer 9, which has the wavelength equal to or smaller than 400 nanometers so that the part of the light is the ultraviolet light; is absorbed to the nano particle. Then, the nano particle converts the absorbed light to light having the wavelength around 585 nanometers. The converted light enters into the solar cell 7 via the sealing layer 5. The other part of the light entered into the wavelength conversion layer 9, which is not converted by the nano particle, penetrates through the layer 9 and enters into the solar cell 7 directly.

In the present embodiment, the part of the light such as the ultraviolet light having the comparatively short wavelength is converted to the light having the comparatively long wavelength, which is effectively utilized in the solar cell 7. Thus, the light entered into the module 1 is effectively utilized, so that the power generation efficiency of the module 1 is high.

Since the light transmission rate of the wavelength conversion layer 9 is high, specifically, since the light transmission rate of the wavelength conversion layer 9 at the wavelength equal to or larger than 500 nano meters is equal to or larger than 90 percents, the converted light effectively enters into the solar cell 7. Thus, the power generation efficiency of the converted light is high.

Further, the module 1 has the high power generation efficiency, and the module 1 is easily manufactured.

Here, in the present embodiment, the nano particle is made of ZnSe:Mn, i.e., the nano particle is made of material of ZnSe, in which Mn is doped. Alternatively, the nano particle may be made of cadmium selenide, cadmium sulfide, zinc cadmium selenide, zinc sulfide, calcium sulfide, mixed crystal of zinc selenide sulfide, mixed crystal of cadmium selenide sulfide, or mixed crystal of zinc selenide cadmium sulfide. Further, the element as the emission center may be Eu, Yb, Er, Cu, or Tb. In these cases, the above advantages of the module 1 having the wavelength conversion layer 9 are obtained.

### Second Embodiment

A solar cell module 31 according to a second embodiment will be explained as follows.

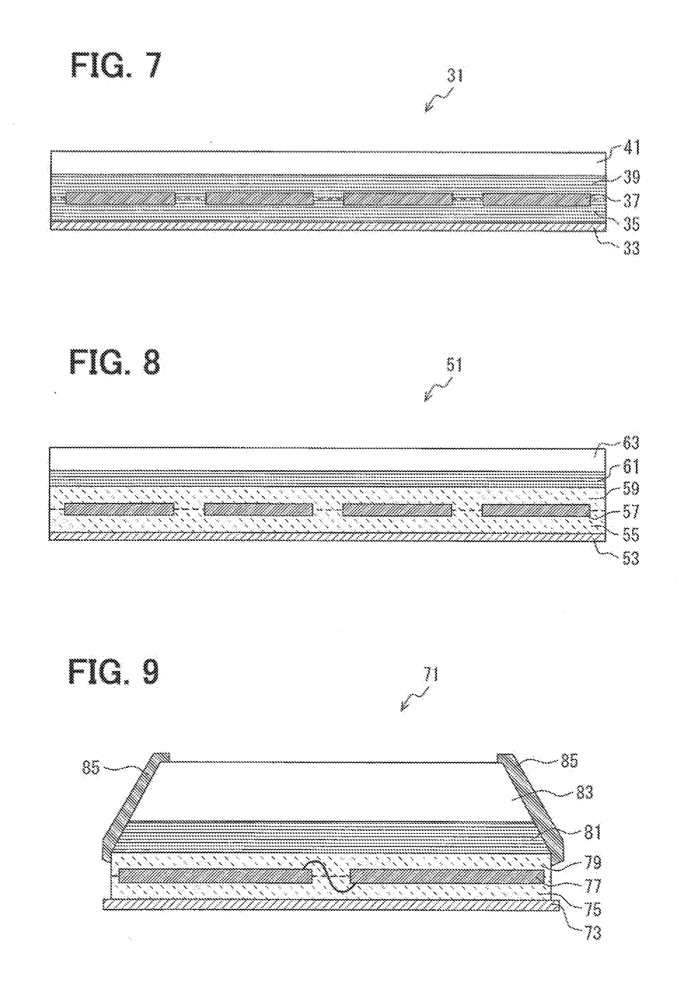

As shown in FIG. 7, the module 31 includes a back sheet 33, a sealing layer 35, a solar cell 37, a wavelength conversion layer 39 and a protection glass 41, which are stacked in this order from the bottom of the module 31.

Specifically, in the present embodiment, the wavelength conversion layer 39 includes wavelength conversion material and sealing material.

When the wavelength conversion layer 39 is formed, the mixed resin material including the nano particle similar to the first embodiment is poured into the sealing material including paste made of ethylene-vinyl acetate polymer or silicone resin, so that composite material is prepared. The composite material is applied to the surface of the sealing layer 35 including the solar cell 37, so that a composite material layer is formed. The composite material layer provides the wavelength conversion layer 39. Alternatively, the composite material may be applied to the surface of the protection glass 41.

The composite material layer and other layers are stacked, similar to the first embodiment. Then, stacked layers are hit-pressed so that the wavelength conversion layer 39 is formed, and the module 31 is completed.

The present embodiment provides the advantages similar to the first embodiment. Further, since the composite material is applied to the solar cell 37, a clearance is not easily formed on the surface of the solar cell 37 and around the solar cell 37.

### Third Embodiment

A solar cell module 51 according to a third embodiment will be explained as follows.

As shown in FIG. 8, the module 51 includes a back sheet 53, a lower sealing layer 55, a solar cell 57, an upper sealing layer 59, a wavelength conversion layer 61 and a protection glass 63, which are stacked in this order from the bottom of the module 51.

Specifically, in the present embodiment, as shown in FIG. 4D, the wavelength conversion layer 61 is formed such that the mixed resin material including the nano particle is dropped on the surface of the protection glass 63 under a condition that the protection glass 63 is rotated, so that the mixed resin material is spin-coated on the protection glass 63, and then, the coated mixed resin material is dried.

Alternatively, as shown in FIG. 4F, the binder for the mixed resin material may be sol-gel glass. In this case, the mixed resin material is applied to the surface of the protection glass 63, and then, the mixed resin material is hardened, so that the mixed resin material is coated on the glass 63.

The present embodiment provides the advantages similar to the first embodiment.

### Fourth Embodiment

A solar cell module 71 according to a fourth embodiment will be explained as follows.

As shown in FIG. 9, the module 71 includes a back sheet 73, a lower sealing layer 75, a solar cell 77, an upper sealing layer 79, a wavelength conversion layer 81 and a protection glass 83, which are stacked in this order from the bottom of the module 71.

Specifically, in the present embodiment, the side wall of the wavelength conversion layer 81 on the outside and the side wall of the protection glass 83 on the outside are cut obliquely so that, when the light reflected on the wavelength conversion layer 81 or the protection glass 83 reaches the side walls of the layer 81 and the glass 83, the layer 81 and the glass 83 reflect the light toward the solar cell 77. For example, the side walls of the layer 81 and the glass 83 tilt 45 degrees to 60 degrees with respect to the horizontal plane. The module 71 further includes a reflection layer 85 for reflecting light, which is arranged on the side walls of the layer 81 and the glass 83.

The reflection layer 85 is made of a metallic reflection tape. The reflection layer 85 may be formed by a deposition method or a sputtering method so that an aluminum film as a thin film for reflecting light is formed on the side walls of the layer 81 and the glass 83.

The present embodiment provides the advantages similar to the first embodiment. Further, since the reflection layer 85 is arranged on the side walls of the layer 81 and the glass 83, when the light reflected on the layer 81 or the glass 83 reaches the side walls, the light effectively enters into the solar cell 77.

### Experimental Examples

An experimental example according to the present embodiment will be explained as follows.

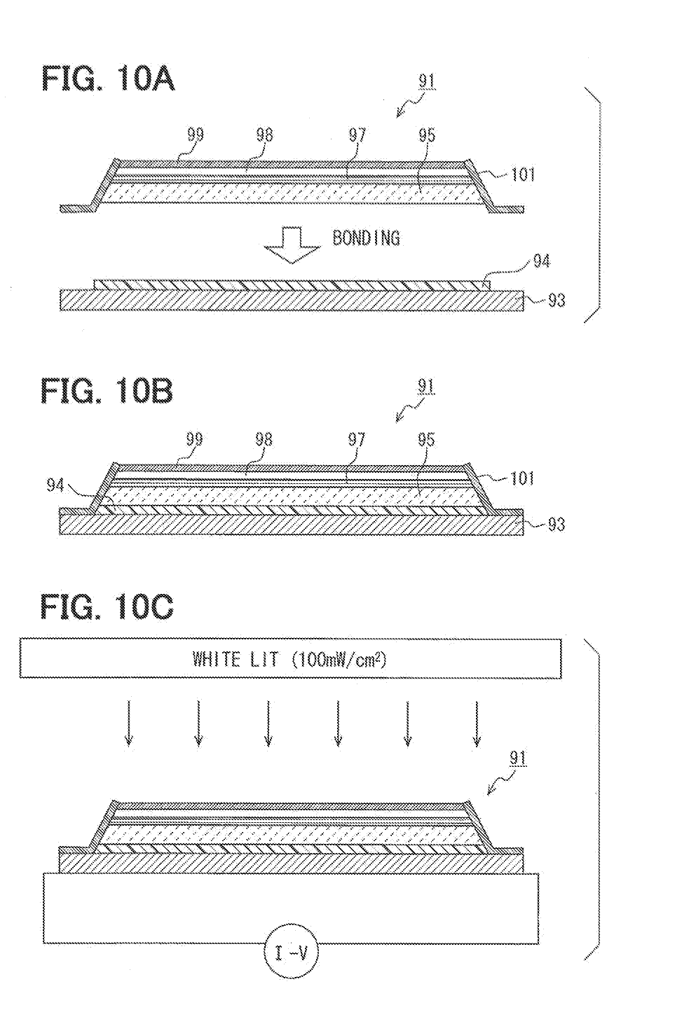

Ten solar cell modules 91 shown in FIGS. 10A and 10B are prepared. The module 91 includes a solar cell 93 as a Si solar cell, which is bonded to a light receiving side structure via an adhesive layer 94. The adhesive layer 94 is made of transparent silicone resin.

Specifically, the module 91 includes the solar cell 93, the adhesive layer 94, a high transparent glass 95, a wavelength conversion layer 97 including the nano particle, a protection glass 98, and an anti-reflection layer 99 for preventing reflection of the light, which are stacked in this order from the bottom of the module 91. Further, the module 91 includes the reflection tape 101 disposed on the side wall of the module 91.

As shown in FIG. 10C, the light output from a light source having the intensity of 100 mW/cm² is irradiated on the module 91. The distance between the light source and the module 91 is about 30 centimeters to 35 centimeters. The light source is, for example, a white light source. The output power of the solar cell 93 is determined according to the current and the voltage generated by the solar cell 93. The results of the measurement of the output power are shown in FIG. 12.

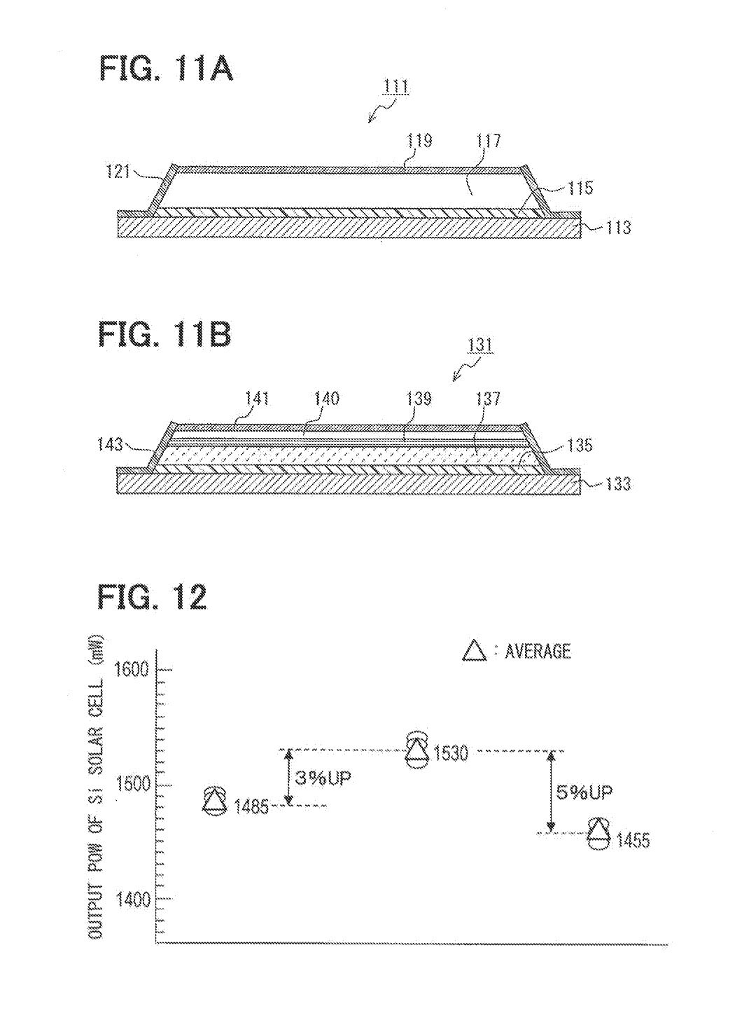

As shown in FIG. 11A, another solar cell module 111 as a first comparison of the present embodiment is prepared. Ten modules 111 are tested. In the module 111, a high transparent glass 117 is bonded to a solar cell 113 via a transparent silicone adhesive 115 as an adhesive layer. An anti-reflection layer 119 is formed on the surface of the high transparent glass 117. Further, a reflection tape 121 is bonded to a side of the module 111, which tilts with respect to the surface of the solar cell 113.

The output of the solar cell 113 is measured with using the module 111, similar to the module 91. The results of measurements of the output power of the cell 113 are shown in FIG. 12.

Further, as shown in FIG. 11B, another solar cell module 131 as a second comparison of the present embodiment is prepared. Five modules 131 are tested. In the module 131, a high transparent glass 137 is bonded to a solar cell 133 via a transparent silicone adhesive 135 as an adhesive layer. A protection glass 140 is bonded to the surface of the high transparent glass 137 via a binder layer 139 made of transparent resin. An anti-reflection layer 141 is formed on the surface of the protection glass 140. Further, a reflection tape 143 is bonded to a side of the module 131, which tilts with respect to the surface of the solar cell 133.

The output of the solar cell 133 is measured with using the module 131, similar to the module 91. The results of measurements of the output power of the cell 133 are shown in FIG. 12.

As shown in FIG. 12, the output power of the solar cell 93 in the module 91 is 1530 mW. The output power of the solar cell 113 in the module 111 is 1485 mW. The output power of the solar cell 133 in the module 131 is 1455 mW. Accordingly, the output power of the solar cell 93 in the module 91 is the most highest.

### Modifications

An anti-reflection layer made of inorganic multi-layered film or having a predetermined surface roughness may be formed on the surface of the protection glass 11, 41, 63, 83, 98 in the module 1, 31, 51, 71, 91.

The forming method of the wavelength conversion layer 9 may be performed by a roll-to-roll method, as shown in FIG. 4E. In this method, a sheet is winded by a roller, and material for providing the wavelength conversion layer is sprayed on and applied to the sheet, so that the wavelength conversion layer is formed on the sheet.

Alternatively, as shown in FIG. 4G, a wavelength conversion layer may be formed on a protection glass, and further, a thin protection glass may be formed on the wavelength conversion layer.

Alternatively, the light other than solar light may be used for the solar cell module.

The above disclosure has the following aspects.

According to an example aspect of the present disclosure, a solar cell module includes: a solar cell; a protection plate having transparency and disposed on a light receiving side of the solar cell; and a wavelength conversion layer converting a wavelength of light and disposed between the solar cell and the protection plate. The wavelength conversion layer includes a particle, which is dispersed in the wavelength conversion layer. The particle absorbs light having a predetermined wavelength. The particle includes an element as a light emission center for emitting light having a wavelength larger than absorbed light.

In the above module, when the light enters into the wavelength conversion layer, the entered light having a comparatively short wavelength is converted to light having a comparatively long wavelength, which corresponds to a type of the element as the light emission center. Although the light having the comparatively short wavelength is not utilized for the solar cell, the converted light having the comparatively long wavelength can be utilized for the solar cell. Thus, the power generation efficiency of the module is improved.

Further, since the module has a simple structure compared with a case where the module includes an input quantum dot and an output quantum dot, the module is easily manufactured. Here, the particle is defined as a nano particle, which has properties similar to the quantum dot. When a structure has a dimension almost corresponds to a wavelength of a de Broglie wave of an atom, the state density of electrons trapped in the structure is discretized. The electrons in the quantum dot are trapped in all three directions.

Alternatively, the particle may have a diameter in a range between 1 nanometer and 20 nanometers. In this case, the particle has properties similar to the quantum dot. Further, the diameter of the particle and the wavelength of the light absorbed in the particle have correlative relationship. When the diameter of the particle is controlled, the wavelength of the light absorbed in the particle is adjusted. Specifically, when the diameter of the particle is in a range between 1 nanometer and 20 nanometers, the wavelength of the absorbed light is adjusted to the comparatively short wavelength such as a wavelength equal to or smaller than 500 nanometers.

Alternatively, the predetermined wavelength of the absorbed light may be smaller than 500 nanometers, and the wavelength conversion layer converts the absorbed light to the light having the wavelength larger than the absorbed light. In this case, the power generation efficiency is improved. Specifically, the power generation efficiency of the silicon solar cell is much improved.

Alternatively, the particle may be made of material having a band gap equal to or larger than 2.48 eV. In this case, when the particle has a band gap larger than a bulk crystal, the wavelength of the absorbed light is smaller than 500 nanometers, for example. This is because the band gap becomes large as the dimensions of the particle are small, according to quantum effects.

Alternatively, the particle may be made of inorganic material. Alternatively, the particle may be made of at least one of zinc selenide, cadmium selenide, cadmium sulfide, zinc cadmium selenide, zinc sulfide, and calcium sulfide. Alternatively, the particle may be made of at least one of mixed crystal of zinc selenide sulfide, mixed crystal of cadmium selenide sulfide, and mixed crystal of zinc selenide cadmium sulfide.

Alternatively, the element as the light emission center may be made of at least one of Mn, Eu, Yb, Er, Cu, and Tb. In this case, the element can emit light having the comparatively long wavelength equal to or larger than 500 nanometers, for example. The power generation efficiency of the solar cell is improved. Specifically, the power generation efficiency of the silicon solar cell is much improved. Since the silicon solar cell effectively converts the light having the wavelength equal to or larger than 400 nanometers to electricity, when the element can emit the light having the comparatively long wavelength, the module effectively generate electric power.

Alternatively, the solar cell may be sealed with resin having transparency. In this case, the solar cell is sealed with transparent resin without clearance.

Alternatively, the wavelength conversion layer may have a light transmission rate of light having a wavelength equal to or larger than 500 nanometers, the light transmission rate being equal to or larger than 90 percents. In this case, when the wavelength conversion layer converts the light to have the comparatively long wavelength, the converted light is effectively entered into the solar cell. Thus, the power generation efficiency of the module is high. Specifically, when the module includes the silicon solar cell, since the silicon solar cell can effectively convert the light having the wavelength equal to or larger than 400 nanometers to the electricity, it is useful for generating electricity because the light transmission rate of the light having the comparatively long wavelength is high.

Alternatively, the wavelength conversion layer may be made of basic material, which is transparent resin or transparent glass. Alternatively, the transparent resin may be ethylene-vinyl acetate polymer or silicone resin. Alternatively, the wavelength conversion layer may be a transparent film, a transparent plate, or a transparent coating film.

Alternatively, at least one of the protection plate and the wavelength conversion layer may have a sidewall, which tilts with respect to a surface of the solar cell. In this case, the light reflected on the protection plate and the wavelength conversion layer and reaching the sidewall thereof can be introduced into the solar cell effectively. Thus, the power generation efficiency of the module is improved.

Alternatively, the module may further include: a reflection film for reflecting light. The reflection film is disposed on the sidewall of the at least one of the protection plate and the wavelength conversion layer. In this case, the light reflected on the protection plate and the wavelength conversion layer and reaching the sidewall thereof can be introduced into the solar cell effectively. Thus, the power generation efficiency of the module is improved.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A solar cell module comprising:
a solar cell;
a protection plate having transparency and disposed on a light receiving side of the solar cell; and
a wavelength conversion layer converting a wavelength of light and disposed between the solar cell and the protection plate,
wherein the wavelength conversion layer includes a particle, which is dispersed in the wavelength conversion layer,
wherein the particle absorbs light having a predetermined wavelength, and
wherein the particle includes an element as a light emission center for emitting light having a wavelength larger than absorbed light.

2. The solar cell module according to claim 1,
wherein the particle has a diameter in a range between 1 nanometer and 20 nanometers.

3. The solar cell module according to claim 1,
wherein the predetermined wavelength of the absorbed light is smaller than 500 nanometers, and
wherein the wavelength conversion layer converts the absorbed light to the light having the wavelength larger than the absorbed light.

4. The solar cell module according to claim 1,
wherein the particle is made of material having a band gap equal to or larger than 2.48 eV.

5. The solar cell module according to claim 1,
wherein the particle is made of inorganic material.

6. The solar cell module according to claim 1,
wherein the particle is made of at least one of zinc selenide, cadmium selenide, cadmium sulfide, zinc cadmium selenide, zinc sulfide, and calcium sulfide.

7. The solar cell module according to claim 1,
wherein the particle is made of at least one of mixed crystal of zinc selenide sulfide, mixed crystal of cadmium selenide sulfide, and mixed crystal of zinc selenide cadmium sulfide.

8. The solar cell module according to claim 1,
wherein the element as the light emission center is made of at least one of Mn, Eu, Yb, Er, Cu, and Tb.

9. The solar cell module according to claim 1,
wherein the solar cell is sealed with resin having transparency.

10. The solar cell module according to claim 1,
wherein the wavelength conversion layer has a light transmission rate of light having a wavelength equal to or larger than 500 nanometers, the light transmission rate being equal to or larger than 90 percents.

11. The solar cell module according to claim 1,
wherein the wavelength conversion layer is made of basic material, which is transparent resin or transparent glass.

12. The solar cell module according to claim 11,
wherein the transparent resin is ethylene-vinyl acetate polymer or silicone resin.

13. The solar cell module according to claim 1,
wherein the wavelength conversion layer is a transparent film, a transparent plate, or a transparent coating film.

14. The solar cell module according to claim 1,
wherein at least one of the protection plate and the wavelength conversion layer has a sidewall, which tilts with respect to a surface of the solar cell.

15. The solar cell module according to claim 14, further comprising:
a reflection film for reflecting light,
wherein the reflection film is disposed on the sidewall of the at least one of the protection plate and the wavelength conversion layer.
